(19) United States
(12) Patent Application Publication
(10) Pub. No.: US 2006/0269879 A1
(43) Pub. Date: Nov. 30, 2006

(54) Method and apparatus for a post exposure bake of a resist

(75) Inventors: Klaus Elian, Bubenreuth (DE); Michael Sebald, Weisendorf (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munich (DE)

(21) Appl. No.: 11/135,634

(22) Filed: May 24, 2005

(51) Int. Cl. G03F 7/20

(52) U.S. Cl. 430/394; 430/330; 430/322

(57) ABSTRACT

Method and Apparatus for A Post Exposure Bake Of A Resist In a Method for patterning a chemically amplified resist layer, the resist layer is provided on a substrate, the resist layer comprising resist molecules in a first state with a first solubility. Predetermined regions of the resist layer are exposed to a first radiation to generate a catalytic species in the exposed predetermined regions of the resist layer. The resist layer is exposed to a second radiation and resist molecules in the predetermined regions of the resist layer are converted from the first state into a second state with a second solubility, the conversion of a resist molecule being catalyzed by the catalytic species, and the activation energy of the catalyzed conversion of the resist molecule being lowered by the absorption of the second radiation in the resist molecule. The resist layer is developed with a predetermined developer.

### TECHNICAL FIELD OF THE INVENTION

The present invention relates to a method for patterning a chemically amplified resist layer and to an apparatus for a post-exposure bake of a chemically amplified resist layer.

### BACKGROUND OF THE INVENTION

When a chemically amplified resist (CAR) is exposed to a laterally modulated intensity of radiation, a latent image of a photoproduct is produced, wherein the photoproduct is typically an acidic photoproduct. In a subsequent post-exposure bake step, the photoresist is heated to an elevated temperature at which the photoproduct catalyzes a conversion of resist molecules thereby altering the solubility properties of the resist layer. Thereby, each molecule of the acidic photoproduct catalyzes the conversion of a plurality of resist molecules. Due to this amplifying process, comparatively low doses are sufficient for lithographic structuring.

During the post-exposure bake, two processes are driven by the elevated temperature, namely the catalyzed conversion which is a chemical reaction and a diffusion of the catalytic species as well as minor products of the chemical reaction. The rate of the chemical reaction is described by a rate constant k_{c}. According to Arrhenius the rate constant k_{c} is a function of the temperature T:
k_{c}∝ exp(−Eₐ/RT)
wherein Eₐ is the activation energy of the chemical reaction and R is the gas constant. Similarly, the rate of the diffusion is described by a rate constant k_{d}, the dependence of which on the temperature T is also approximately described by an Arrhenius law:
k_{d}∝ exp(−E_{d}/RT)
wherein E_{d} is the activation energy for single motion steps in the diffusion.

Diffusion of the catalytic species is important for the transport of each single molecule of the catalytic species from one resist molecule to another resist molecule. Without diffusion, one molecule of the catalytic species could merely catalyze the conversion of one single resist molecule and there was no amplifying effect.

However, diffusion of the catalytic species also blurs the image. Therefore, a minimum k_{d} and a maximum k_{c} is desired. However, as can be seen from the above equations, for given activation energies Eₐ, E_{d}, a fast chemical reaction is achieved at a high temperature T and accompanied by a pronounced diffusion. Little diffusion is achieved at a low temperature T but accompanied by a slow chemical reaction.

The blur caused by diffusion in chemically amplified resists seems to be typically in the order of 10 nm or slightly above. As long as the wavelength used for lithography and the critical dimension (CD) were large compared to the range of diffusion, the problem of diffusion was negligible. However, with preceding miniaturization of microelectronic and micromechanic devices the CD approaches the order of magnitude of the range of diffusion and the blur caused by the diffusion cannot be neglected anymore.

As can be seen from the above equations, the rate of the catalyzed chemical reaction can be increased without increasing the rate of diffusion by lowering the activation energy Ea of the chemical reaction. This approach leads from the so-called high activation energy resists to the so-called low activation energy resists. While the post exposure bake of a high activation energy resist is typically performed between 80° C. and 150° C., a low activation energy resist needs considerably lower post exposure bake temperatures down to room temperature.

However, there are important drawbacks of low activation energy resists. In particular, due to the low activation energy, the chemical reaction converting the resist molecules already takes place during the exposure. Reaction products evaporate from the resist layer and condense on surfaces of lenses and other optical facilities. Furthermore, since the activation energy in absence of a catalytic species is reduced as well, low activation energy resists provide a reduced shelf life. For the same reason, the freshly applied unexposed resist layer needs to be dried at reduced temperatures and it is difficult to achieve a compact and mechanically robust resist layer.

An overview over modern resists is given in “Deep-UV resist: Evolution and status” by Hiroshi Ito (Solid State Technology, July 1996, pp. 164-170). Lithography with a low activation energy chemically amplified photoresist is described in “Sub-50 nm Half Pitch Imaging with a Low Activation Energy Chemically Amplified Photoresist” by G. M. Wallraff et al. (Journal of Vacuum Science & Technology, Vol. 22, Issue 6, pp. 3479-3484, November 2004).

### SUMMARY OF THE INVENTION

The present invention provides a method for patterning a chemically amplified resist layer and an apparatus for a post exposure bake of a chemically amplified resist layer which reduce the blur caused by diffusion of the catalytic species.

One embodiment of the present invention is a method for patterning a chemically amplified resist layer, comprising providing the resist layer on a substrate, the resist layer comprising resist molecules in a first state with a first solubility; exposing predetermined regions of the resist layer to a first radiation to generate a catalytic species in the exposed predetermined regions of the resist layer; exposing the resist layer to a second radiation and converting resist molecules in the exposed predetermined regions of the resist layer from the first state into a second state with a second solubility, the conversion of a resist molecule being catalyzed by the catalytic species, and the activation energy of the catalyzed conversion of the resist molecule being lowered by the absorption of the second radiation in the resist molecule; and developing the resist layer with a predetermined developer.

Furthermore, in another embodiment of the present invention there is an apparatus for a post exposure bake of a chemically amplified resist layer with a latent image of a catalytic species, the apparatus comprising a location for a substrate with the resist layer; a heat source for heating the resist layer to an elevated temperature when the substrate is arranged at the location; and a light source for illuminating the resist layer while the substrate is arranged at the location and the elevated temperature of the substrate is maintained, for converting resist molecules in the exposed predetermined regions of the resist layer from the first state into a second state with a second solubility, wherein the conversion of a resist molecule is catalyzed by the catalytic species and assisted by the absorption of the second radiation in the resist molecule.

In another embodiment of the present invention, the chemical reaction is assisted during the post exposure bake of a chemically amplified resist layer with a latent image of a catalytic species by an exposure to photons. The catalytic species catalyzes a chemical reaction converting resist molecules from a first state with a first solubility to a second state with a second solubility. The photon energy is selected such that no additional molecules of the catalytic species are generated but the activation energy of the catalyzed chemical reaction is lowered. As a consequence, the conversion of the resist molecules is faster and the time and/or the temperature of the post exposure bake can be reduced. Both a reduction of the time and a reduction of the temperature of the post exposure bake reduce the diffusion of the catalytic species and the blur of the image. Depending on the resist and the chemistry of the catalyzed conversion and the wavelength and dose of the additional exposure, or Illumination, the temperature of the post exposure bake can be considerably reduced (even to room temperature) and/or the post exposure bake time can be reduced to a fraction.

When the post exposure bake is replaced by a post exposure illumination at room temperature, no heat source is required and the apparatus is simplified correspondingly. When the post exposure bake is performed at reduced temperature above room temperature, the heat source and the light source are preferably arranged on opposite sides of the location provided for a substrate with the resist layer. Preferably, the backside of the substrate is in contact with the heat source.

In order to achieve a laterally homogeneous intensity on the resist layer, it is advantageous to use a plurality of light emitters essentially arranged in a plane parallel to the resist layer. An exhaust facility draining gaseous reaction products comprises a plurality of nozzles arranged between the resist layer and the light emitters. Alternatively, the light emitters are arranged between the exhaust facility and the resist layer.

It is important to note that the effect of the exposure to light during the post exposure bake according to the present invention is not a thermal effect. Of course, a large dose of light heats the resist layer and increases its temperature and thereby also increases the chemical reaction as well as the rate of diffusion. In contrast to such a thermal effect, according to the present invention a photon is absorbed in a resist molecule. The energy of the absorbed photon directly causes a transition of the resist molecule to an excited electronic or vibrational state which provides a lower activation energy for the catalyzed conversion of the resist molecule to a state with different solubility.

Depending on the chemistry of the resist, not each excited state of a resist molecule provides a reduced activation energy. Therefore, it is advantageous that the photon energy equals the energy required to excite the resist molecule to a state with reduced or even minimum activation energy. In this way, the effect of the illumination during the post exposure bake is focused on the direct reduction of the activation energy and a low dose is required, a minimum or even negligible heating effect occurs and diffusion remains low.

The absorption of the photon and the transition of the resist molecule to the excited state with reduced activation energy may take place before a molecule of the catalytic species forms a complex with the resist molecule. In this case, the life time of the excited state of the resist molecule should be as long as possible in order to maximize the probability that a molecule of the catalytic species forms a complex with the resist molecule before the excited state decays.

As an alternative, the photon is absorbed in the complex formed by the resist molecule and a molecule of the catalytic species. Preferably, the photon is selectively absorbed by the complex, but not by the resist molecule alone or any other component in the resist layer.

As a further alternative, the photon is absorbed in the molecule of the catalytic species before the formation of a complex with a resist molecule. In this case again, a life time as long as possible of the excited state of the catalytic molecule is advantageous in order to have a maximum probability that each single photon assists in a conversion of a resist molecule.

Due to the very specific effect of the photons and in particular when the probability for each absorbed photon to induce or assist the conversion of a resist molecule is high, rather low photon doses are required and there is almost no effect on the temperature since the total energy transferred to the resist layer by the illumination is smaller than the total energy transferred from the heat source to the substrate.

The catalytic species is generated during a first exposure of the resist layer to a photon, electron or ion radiation with a laterally modulated intensity. The energy of each photon or other particle of the radiation is above a predefined threshold for the production of the catalytic species. During the post exposure bake, according to the present invention, the resist layer is illuminated with a laterally more or less homogeneous intensity and a photon energy below that threshold. However, if there are areas in the resist layer where the latent image of the catalytic species is intended not to be converted into a latent image of the solubility of the resist molecules, these areas are not illuminated during the post exposure bake.

### BRIEF DESCRIPTION OF THE DRAWINGS

The invention is described below in more detail with reference to exemplary embodiments and the drawings, in which:

FIG. 1 is a flow chart illustrating a method according to the present invention.

FIGS. 2 and 3 show the decrease of the activation energy of a chemical reaction.

FIGS. 4 to 6 show representations of apparatuses for a post exposure bake of a resist layer.

### DETAILED DESCRIPTION OF THE INVENTION

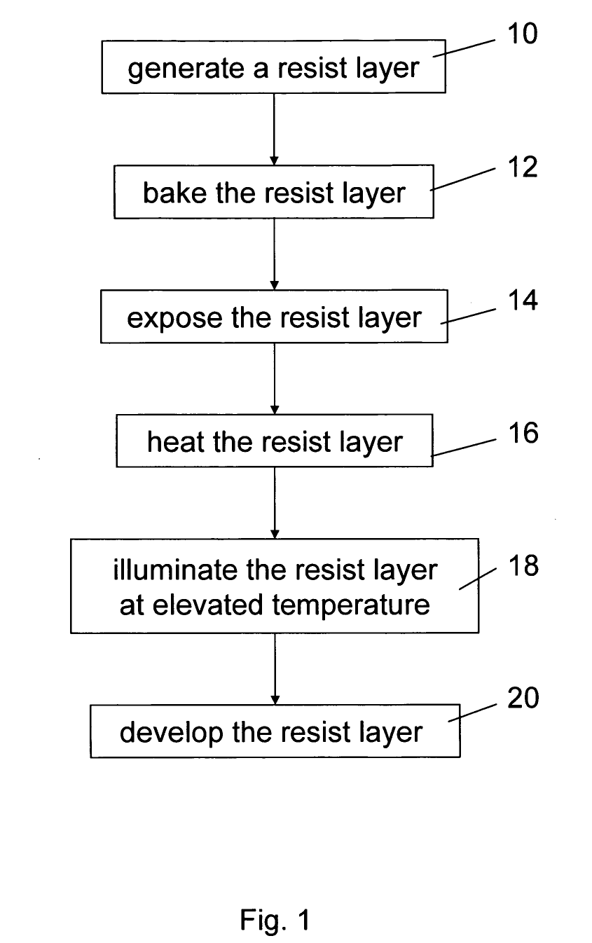

FIG. 1 is a flow diagram of a method for patterning a chemically amplified resist layer according to the present invention. In a first step 10, a resist layer is generated on a substrate. The surface of the substrate is coated with a liquid solution of the resist material in a solvent. Preferably, a spin coater is used to produce a thin layer with laterally homogeneous thickness.

An example of the resist is a high activation energy resist, a mixture of 6.0 g terpolymer (22.5 mol-% tertbutylmethacrylat, 50 mol-% maleicanydride, 22.5 mol-% allylsilane, 5 mol-% ethoxyethylmethacrylat), 0.35 g triphenylsulfonium-hexafluorpropansulfonat (photoacid precursor) and 0.05 g trioctylamin (basic additive) in 93.6 g 1-methoxy-2-propylacetat (solvent). As a preferred example, the liquid solution of the resist in the solvent is coated on the substrate at 2000 rpm in 20 s.

In a second step 12, the resist layer is heated to an elevated temperature. The solvent evaporates and the remaining resist material forms a compact layer which is sufficiently mechanically robust for the subsequent treatment and the final utilization as a mask. Preferably the resist is dried on a hotplate with 120° C. in 90 s, resulting in a 210 nm thick solid film. The resist layer now essentially includes what will subsequently be called resist molecules in a first state and a precursor of a catalytic species.

Throughout this application, the term resist molecule is used for the molecule or the molecules in the resist layer which is or are present in at least two different states with different solubility. These states may differ by the existence (first state) and absence (second state) of protecting groups. Alternatively the states of the resist molecules differ by the degree of polymerization. Furthermore, the first state may be convertible, or transformable, to the second state by any other chemical reaction between a resist molecule and a auxiliary molecule, between a number of equal or unequal resist molecules.

In a third step 14, the resist layer is exposed to a first radiation. This first radiation is preferably a photon or electron or ion radiation wherein photon radiation includes all parts of the electromagnetic spectrum, in particular visible, UV and X-ray radiation. For example for a CD in the range of 100 nm or several 10 nm, deep ultraviolet radiation (DUV) or extreme ultraviolet radiation (EUV) is used.

The intensity and the dose of the first radiation in the resist layer is laterally modulated such that predetermined regions are exposed to the first radiation and other regions are not or almost not exposed. In case of photon radiation, this laterally modulated intensity is preferably generated by means of a lens and/or other imaging facilities imaging a reticle.

In the predetermined regions exposed to the first radiation, the precursor of the catalytic species is converted to the catalytic species. Thus, the exposure to the first radiation produces a latent image of catalytic species in the resist layer. Preferably the catalytic species is a sulfonic acid or another acid.

The catalytic species has the potential to catalyze the conversion of the resist molecules from the first state with a first solubility to a second state with the second solubility. The activation energy Ea of the catalyzed conversion of the resist molecules is such that the conversion does not or essentially not take place during the exposure to the first radiation which is preferably performed at room temperature or slightly above.

In a fourth step 16, the resist layer is heated to an elevated temperature. For a conventional post exposure bake, the elevated temperature would be high enough (typically 130° C. to 150° C.) and maintained long enough (typically 90 s to 120 s) for the catalytic species to catalyze the conversion of the resist molecules from the first to the second state.

According to the present invention, the elevated temperature is lower (preferably 60° C. to 120° C.) and/or maintained for a shorter period of time (preferably 5 s to 120 s, more preferably 5 s to 60 s) such that without any additional measure the conversion of the resist molecules would be highly incomplete and only a fraction or a small fraction of the resist molecules would be converted. As an example, the resist layer is heated to 90° C. for a period of 60 s.

According to the present invention, during and/or after the resist layer (and preferably also the substrate) is heated to the elevated temperature, the resist layer is illuminated or exposed to a second radiation while the elevated temperature is maintained. The second radiation is a photon radiation and if the first radiation is a photon radiation, as well, the photo-energy of the second radiation is lower. Usually, a photon energy threshold for the conversion of the precursor to the catalytic species exists. The photon energy of the second radiation is below this threshold while the photon energy of the first radiation (in the case of photon radiation) is above this threshold. Thus, the exposure to the second radiation does not cause the generation of additional molecules of the catalytic species.

However, regarding the dose and the number of photons of each the first and second radiation, it is noted that the total number of photons and the dose of the second radiation are preferably higher than the number of photons and the dose, respectively, of the first radiation.

The intensity and dose of the second radiation are preferably essentially laterally homogeneous, i.e. both the predetermined regions exposed to the first radiation in the third step 14 and other regions not exposed to the first radiation are exposed to the second radiation. With the resist being optimized for DUV exposure with wavelengths smaller than 250 nm, the wavelength of the second radiation is preferably between 250 nm and 10 μm.

The elevated temperature and the exposure to the second radiation act together and cause a quick conversion of the resist molecules. The second radiation compensates the low temperature and/or the short period of time during which the elevated temperature is maintained. A broad variety of microscopic or photochemical mechanisms for the action of the simultaneous exposure to heat and the second radiation is advantageous. However, all of these photochemical mechanisms have in common that the effect of the second radiation is not or only to a negligible degree a thermal effect.

In particular, the power and the total energy of the second radiation absorbed in the resist layer and the substrate beneath are too low in order to considerably increase the temperature of the resist layer. In other words, the power transferred to the resist layer or to the resist layer and the substrate is smaller or much smaller than or even negligible compared to the heating power transferred from the heat source to the substrate and the resist layer. This also means that the power transferred to the resist layer and the substrate by the second radiation is considerably lower than or even negligible compared to the power emitted from the resist layer and the substrate to their ambience via infrared radiation and heat conduction.

The second radiation may be applied to the resist layer as a continuous illumination with constant intensity within one continuous period of time. Alternatively, the second radiation may be applied to the resist layer in a number of short periods of time or in a number of flashes. In particular in the case of short time high intensity flashes, the above considerations regarding the power of the second radiation rather refer to a time average of the power than to the momentary power in a single flash. An advantage of an exposure with a constant low intensity of the second radiation is that not even for a very short period of time the temperature of the resist layer can be increased by a high momentary intensity. An advantage of an exposure with flashes of the second radiation is that inexpensive flash lamps with rather cold light with a low portion of heat radiation.

There are countless photochemical mechanisms of catalyzed and photon-assisted conversions of a resist molecule. These may roughly be classified by the site and the time of absorption of the second radiation photon. The photon may be absorbed in the molecule of the catalytic species or in the resist molecule or one of a plurality of different resist molecules. The photon may be absorbed before the catalytic molecule attaches itself to the resist molecule or when both molecules already form a complex. In the case of the photon being absorbed before both molecules form a complex, it is important that the life time of the excited state generated by the absorption of the photon is as long as possible for a maximum probability for the formation of the complex before the decay of the excited state. The longer the life time is, the smaller are the required number of photons (i.e. the dose) and the thermal effect of the second radiation.

Result of the chemical reaction catalyzed by the catalytic species and assisted by the absorption of a second radiation photon is the conversion of the resist molecule to a second state with a second solubility. One example for the chemical reaction is the separation of a protecting group from the resist molecule. The separation itself changes the solubility of the resist molecule in a developing step subsequently described. Alternatively, resist molecules without protecting group polymerize instantaneously or subsequently, whereby the polymerized resist molecules represent the above-mentioned second state with a second solubility. As a further alternative, the catalytic species directly catalyzes a polymerization of the resist molecules without a separation of a protecting group.

After the predetermined elevated temperature of the resist layer has been maintained for a predetermined period of time during which the resist layer has been exposed to a predetermined dose of the second radiation, the temperature is decreased e.g. to room temperature. Subsequently, the resist layer is developed in a sixth step 20. For this purpose, it is immersed into a developer. After the treatment of the third, fourth and fifth steps 14, 16 and 18 described above, the resist molecules in the predetermined regions exposed to the first radiation are in the second state while resist molecules in other regions not exposed to the first radiation are in the first state. Both states differ in the solubility of the resist molecules in the developer. One of both states is dissolved while the other continues to form a compact resist layer on the substrate. As an example, for a positive tone resist, the catalytic separation of protecting groups increases the solubility of the resist molecules in the developer. As an example for a negative-tone resist, the catalytic species catalyzes a polymerization of resist molecules via polymerizable groups.

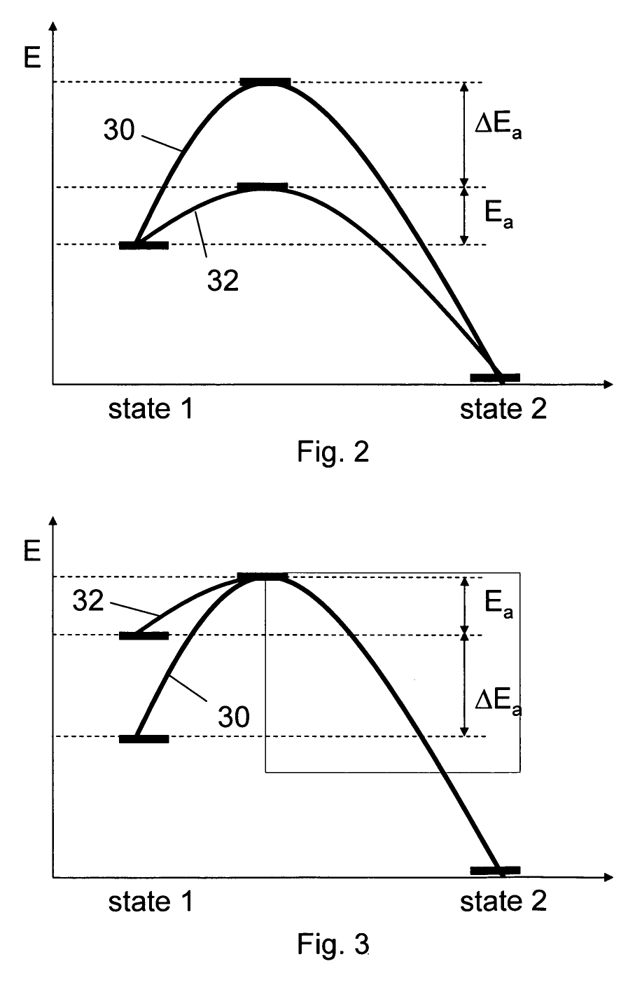

FIGS. 2 and 3 are schematic diagrams illustrating the decrease of the activation energy of the chemical reaction converting the resist molecules from the first to the second states. In both FIGS. 2 and 3, the reaction coordinate is assigned to the abscissa and the energy is assigned to the ordinate. The diagrams display the energy of the resist molecule in the first state (state 1) and the second state (state 2) and the intermediate states. The energies of state 1 and state 2 are different from each other. In these examples, the energy of state 1 is higher than the energy of state 2. However, the energy of state 2 may be at least slightly higher than the energy of state 1, as well.

The diagrams of FIGS. 2 and 3 are simplified. The complex formed by a resist molecule and the molecule of the catalytic species and its energies before and after the conversion of the resist molecules are not displayed. The presence of a catalytic species and its effect are implicated only insofar as the energies of the intermediate states would be higher or much higher without the presence and involvement of a catalytic species.

If the conversion from the first state to the second state is a chemical reaction between a plurality of molecules or a decay or a division of a molecule on a plurality of molecules, the energies of state 1 and state 2 refer to the entirety of all the educts and the entirety of all the products, respectively.

For all the intermediate states the energy E is higher than the energy of state 1. Thus, the activation energy Eₐ or Eₐ+ΔEₐ needs to be supplied initially during the conversion from state 1 to state 2. The activation energy for a conversion in a conventional post exposure bake (trace 30) and the activation energy for conversion in the inventive process including exposure to the second radiation (trace 32) are different. The activation energy Eₐ with exposure to the second radiation is smaller than the activation energy Eₐ+ΔEₐ in a conventional post exposure bake without exposure to the second radiation. According to the Arrhenius law, reduction of the activation energy by ΔEₐ increases the rate of the conversion.

In FIGS. 2 and 3, two examples of reducing the activation energy are displayed. FIG. 2 shows an example in which the activation energy is reduced by a reduction of the maximum energy of the intermediate states between the states 1 and 2. FIG. 3 shows an example in which the activation energy is reduced by increasing the energy of state 1.

The diagram of FIG. 2 describes the case of absorption of a second radiation photon in a catalytic species molecule. The thereby excited catalytic species molecule has an improved catalytic effect on the conversion, i.e. compared to the non-excited catalytic species molecule the activation energy of the conversion is further reduced by ΔEₐ. Furthermore, the diagram of FIG. 2 describes a case in which the second radiation photon is absorbed in the resist molecule but the energy of the second radiation photon is very small compared to the activation energy and thus the energy of state 1 is (almost) not altered by the absorption of the second radiation photon. In this case, the effect of the absorption of a second radiation photon in the resist molecule is the transfer of the resist molecule into an electronic or vibrational configuration which can be transformed to the second state more easily because of quantum-mechanical reasons.

FIG. 3 describes the case of absorption of the second radiation photon in the resist molecule transferring the resist molecule into an excited modification of state 1. In this case, the energy of the second radiation photon equals the amount of energy ΔEₐ by which the activation energy is reduced.

The diagrams of FIGS. 2 and 3 are schematic and exemplary descriptions of the mechanisms reducing the activation energy by exposure to the second radiation. Numerous other mechanisms are conceivable and possible and are within the scope of the present invention although not described in detail herein.

Due to the reduction of the activation energy from Eₐ+ΔEₐ to Eₐ, the temperature and/or the time of the post exposure bake can be reduced. The required temperature may even be reduced to room temperature by the inventive exposure to the second radiation. In this case, the post exposure bake is rather replaced than assisted by a post exposure illumination and no heat source is required.

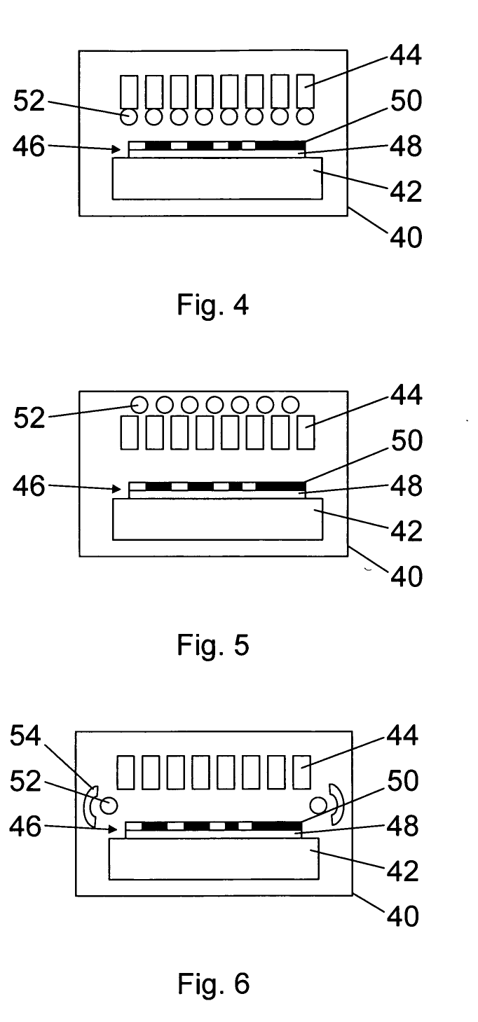

FIGS. 4 to 6 are schematic cross-sectional views of apparatuses for a post exposure bake of a resist layer according to the present invention. The apparatus is a modification of a hot plate module. Within a housing 40, a hot plate 42, or heated chuck, and an exhaust facility comprising a number of nozzles 44 are arranged opposite to each other. The nozzles 44 of the exhaust facility are preferably arranged in a one- or two-dimensional array and essentially in a plane parallel to the hot plate 42. A predetermined location 46 for a substrate 48 with a resist layer 50 is between the hot plate 42 and the nozzles 44 such that the backside of the substrate 48 is in contact with the hot plate 42. Black and white regions represent those areas within the resist layer 50 which comprise or do not comprise, respectively, the catalytic species.

The embodiments displayed in FIGS. 4 to 6 differ in the arrangement of the light source within the housing 40. In the embodiment displayed in FIG. 4, the light source comprises a plurality of light emitters 52 between the nozzles 44 and the location 46 for the substrate 48. Preferably, the light emitters 52 are dot-like and arranged in an essentially plane two-dimensional array or they are linear and arranged in parallel to each other in an essentially plane one-dimensional array.

The embodiment displayed in FIG. 5 differs from the embodiment described above with reference to FIG. 4 in that the nozzles 44 are arranged between the light emitters 52 and the location 46 and the light from the light emitters 52 is transmitted to the resist layer 50 through voids between the nozzles 44. In both embodiments described above with reference to FIGS. 4 and 5, the arrangement of the light emitters 52 preferably corresponds to the arrangement of the nozzles 44 or the voids between the nozzles, respectively.

FIG. 6 displays an embodiment in which the light source comprises one or several light emitters 52 that are arranged peripherally to the location 46 for the substrate 48. A part of the light emitted from the light emitters 52 is reflected by one or several mirrors 54 in order to achieve an essentially constant intensity of light on the resist layer 50.

1. A method for patterning a chemically amplified resist layer, comprising:
providing the resist layer on a substrate, the resist layer comprising resist molecules in a first state with a first solubility;
exposing predetermined regions of the resist layer to a first radiation to generate a catalytic species in exposed predetermined regions of the resist layer;
exposing the resist layer to a second radiation and converting resist molecules in the predetermined regions of the resist layer from the first state into a second state with a second solubility, the conversion of a resist molecule being catalyzed by the catalytic species, and the activation energy of the catalyzed conversion of the resist molecule being lowered by absorption of the second radiation in the resist molecule; and
developing the resist layer with a predetermined developer.

2. A method for patterning a chemically amplified resist layer, comprising:
providing the resist layer on a substrate, the resist layer comprising resist molecules in a first state with a first solubility;
exposing predetermined regions of the resist layer to a first radiation to generate a catalytic species in exposed predetermined regions of the resist layer;
heating the substrate with the resist layer to an elevated temperature by means of a heat source and exposing the resist layer to a second radiation while the elevated temperature of the resist layer is maintained to convert resist molecules in the predetermined regions of the resist layer from the first state into a second state with a second solubility, and the conversion of a resist molecule being catalyzed by the catalytic species and assisted by absorption of the second radiation in the resist molecule; and
developing the resist layer with a predetermined developer.

3. The method according to claim 2, wherein the second radiation is a photon radiation and the activation energy of the catalyzed conversion of the resist molecule is lowered by the absorption of a photon of the second radiation in the resist molecule.

4. The method according to claim 1, wherein the second radiation is a photon radiation and the absorption of a photon of the second radiation lowers said activation energy by changing the electronic state of the resist molecule.

5. The method according to claim 2, wherein the second radiation is a photon radiation and the absorption of a photon of the second radiation lowers said activation energy by changing the electronic state of the resist molecule.

6. The method according to claim 1, wherein the second radiation is a photon radiation and the absorption of a photon of the second radiation lowers said activation energy by changing the vibrational state of the resist molecule.

7. The method according to claim 2, wherein the second radiation is a photon radiation and the absorption of a photon of the second radiation lowers the activation energy by changing the vibrational state of the resist molecule.

8. The method according to claim 2, wherein the second radiation is radiated from a radiation source, the radiation source and the heat source being located at opposite sides of the substrate.

9. The method according to claim 2, wherein the total energy transferred to the resist layer by the second radiation is smaller than the total energy transferred from the heat source to the substrate.

10. The method according to claim 1, wherein for production of the catalytic species a photon energy threshold exists, and wherein the photon energy of the second radiation is below said photon energy threshold.

11. The method according to claim 3, wherein for production of the catalytic species a photon energy threshold exists, and wherein the photon energy of the second radiation is below said photon energy threshold.

12. The method according to claim 1, wherein the resist layer is exposed to a number of flashes of the second radiation.

13. The method according to claim 3, wherein the resist layer is exposed to a number of flashes of the second radiation.

14. The method according to claim 1, wherein
in the step of converting, protecting groups are separated from resist molecules, and
resist molecules with the protecting group provide the first solubility and resist molecules without the protecting group provide the second solubility which is different from the first solubility.

15. The method according to claim 2, wherein in the step of converting, protecting groups are separated from resist molecules, and
resist molecules with the protecting group provide the first solubility and resist molecules without the protecting group provide the second solubility which is different from the first solubility.

16. The method according to claim 14, wherein in the step of developing, resist molecules without protecting group are dissolved.

17. The method according to claim 15, wherein in the step of developing, resist molecules without protecting group are dissolved.

18. The method according to claim 1, wherein in the step of converting, protecting groups are separated from resist molecules, and resist molecules without protecting group are polymerized.

19. The method according to claim 2, wherein in the step of converting, protecting groups are separated from resist molecules, and resist molecules without protecting group are polymerized.

20. The method according to claim 1, wherein the conversion of the resist molecules is a polymerization of the resist molecules catalyzed by the catalytic species.

21. The method according to claim 2, wherein the conversion of the resist molecules is a polymerization of the resist molecules catalyzed by the catalytic species.

22. The method according to claim 2, wherein the first radiation is selected from the group consisting of light, X rays, electron radiation and ion radiation.

23. The method according to claim 1, wherein the resist layer is baked before the steps of exposing.

24. An apparatus for a post exposure bake of a chemically amplified resist layer with a latent image of a catalytic species, the apparatus comprising:
a location for a substrate with the resist layer;
a heat source for heating the resist layer to an elevated temperature when the substrate is arranged at the location; and
a light source for illuminating the resist layer while the substrate is arranged at the location and the elevated temperature of the substrate is maintained, for converting resist molecules in the exposed predetermined regions of the resist layer from the first state into a second state with a second solubility, wherein the conversion of a resist molecule is catalyzed by the catalytic species and assisted by the absorption of the second radiation in the resist molecule.

25. The apparatus according to claim 24, wherein the heat source and the light source are arranged at opposite sides of the location provided for the substrate.

26. The apparatus according to claim 24, wherein the light source comprises a plurality of light emitters essentially arranged in a plane parallel to the location.

27. The apparatus according to claim 26, wherein the plurality of light emitters are arranged between the location and an exhaust facility.

28. The apparatus according to claim 26, wherein an exhaust facility is arranged between the location and the plurality of light emitters.

29. The apparatus according to claim 24, wherein an exhaust facility is arranged opposite to the location and the light source is arranged peripheral to the location and the exhaust location.
